(19) United States
(12) Patent Application Publication
(10) Pub. No.: US 2026/0052756 A1
(43) Pub. Date: Feb. 19, 2026

(54) SEMICONDUCTOR DEVICE

(71) Applicant: FUJI ELECTRIC CO., LTD., Kanagawa (JP)

(72) Inventors: Kosuke YOSHIDA, Matsumoto-city (JP); Tatsuya NAITO, Matsumoto-city (JP); Ryutaro HAMASAKI, Matsumoto-city (JP)

(21) Appl. No.: 19/369,284

(22) Filed: Oct. 26, 2025

Related U.S. Application Data
(63) Continuation of application No. PCT/JP2024/035952, filed on Oct. 8, 2024.

(30) Foreign Application Priority Data
Nov. 29, 2023 (JP) 2023-201405

(51) Int. Cl. H10D 84/00

(52) U.S. Cl. CPC H10D 84/161

(57) ABSTRACT

Provided is a semiconductor device comprising: a transistor portion and a diode portion; and a plurality of trench portions. The transistor portion may include: a plurality of trench bottom regions that are provided repeatedly; and a plurality of trench bottomless regions that are sandwiched between the plurality of trench bottom regions. The diode portion may have: a back-surface-side region including a first conductivity type portion and a second conductivity type portion. The diode portion may have a repetitive structure in which a region in which the second conductivity type portion is formed and a region in which the second conductivity type portion is not formed are alternately and repeatedly arrayed. In a top view, a shortest distance from each end portion of the plurality of trench bottomless regions to a second conductivity type non-forming region may be 85% or more and 115% or less of a predetermined reference value.

The contents of the following patent application(s) are incorporated herein by reference:
NO. 2023-201405 filed in JP on Nov. 29, 2023
NO. PCT/JP2024/035952 filed in WO on Oct. 8, 2024.

### BACKGROUND

### 1. Technical Field

The present invention relates to a semiconductor device.

### 2. Related Art

In Patent document 1, described is that “below the bottom of the exposed trenches 14, 15, 16, a plurality of doping regions (for example, an implantation region) 1059 of a second conductivity type (which is complementary to the first conductivity type) is generated.”. In Patent document 2, described is that “a FWD region 19a with a narrow width” and “a FWD region 19b with a wide width” are provided.

### RELATED ART DOCUMENTS

Patent document
Patent Document 1: Japanese Patent Application Publication No. 2019-110288
Patent Document 2: Japanese Patent No. 5637175

### BRIEF DESCRIPTION OF THE DRAWINGS

FIG. 1A shows an example of a top view of a semiconductor device 100.

FIG. 1B shows an enlarged view of an end portion of an active region 110 in the top view of the semiconductor device 100.

FIG. 1C shows an example of a cross section a-a′ in FIG. 1B.

FIG. 1D shows a modified example of a cross section a-a′ in FIG. 1B.

FIG. 1E shows a modified example of a cross section a-a′ in FIG. 1B.

FIG. 2A shows an example of the top view of the semiconductor device 100.

FIG. 2B shows a modified example of the top view of the semiconductor device 100.

FIG. 2C shows a modified example of the top view of the semiconductor device 100.

FIG. 2D shows a modified example of the top view of the semiconductor device 100.

FIG. 3A shows a modified example of the top view of the semiconductor device 100.

FIG. 3B shows a modified example of the top view of the semiconductor device 100.

FIG. 4 shows a modified example of the top view of the semiconductor device 100.

FIG. 5 shows an example of a top view of a semiconductor device 500 of a comparative example.

FIG. 6A shows an example of the top view of the semiconductor device 200.

FIG. 6B shows an example of a top view of the semiconductor device 200.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to a solution of the invention.

In the present specification, one side in a direction parallel to a depth direction of a semiconductor substrate is referred to as an “upper” side, and another side is referred to as a “lower” side. One surface of two principal surfaces of a substrate, a layer or another member is referred to as an upper surface, and another surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described by using orthogonal coordinate axes of an X axis, a Y axis, and a Z axis. The orthogonal coordinate axes merely specify relative positions of components, and do not limit a particular direction. For example, the Z axis is not limited to indicate a height direction with respect to the ground. It is to be noted that a +Z axis direction and a −Z axis direction are directions opposite to each other. When the Z axis direction is described without describing a sign, it means that the direction is parallel to the +Z axis and the −Z axis.

In the present specification, a surface parallel to the upper surface of the semiconductor substrate is referred to as the XY surface, and an orthogonal axis parallel to the upper surface and the lower surface of the semiconductor substrate is referred to as the X axis and the Y axis. In addition, an axis perpendicular to the upper surface and the lower surface of the semiconductor substrate is referred to as the Z axis. The depth direction of a semiconductor substrate may be referred to as the Z axis. It should be noted that, in the present specification, a case where the semiconductor substrate is viewed in the Z axis direction is referred to as a plan view. In addition, in the present specification, a direction parallel to the upper surface and the lower surface of the semiconductor substrate may be referred to as a horizontal direction, including an X axis direction and a Y axis direction.

Each embodiment shows an example in which a first conductivity type is set as an N type, and a second conductivity type is set as a P type; however, the first conductivity type may be the P type, and the second conductivity type may be the N type. In this case, conductivity types of a substrate, a layer, a region, and the like in each embodiment respectively have opposite polarities.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state.

In the present specification, a description of a P+ type or an N+ type means a higher doping concentration than that of the P type or the N type, and a description of a P-type or an N−type means a lower doping concentration than that of the P type or the N type.

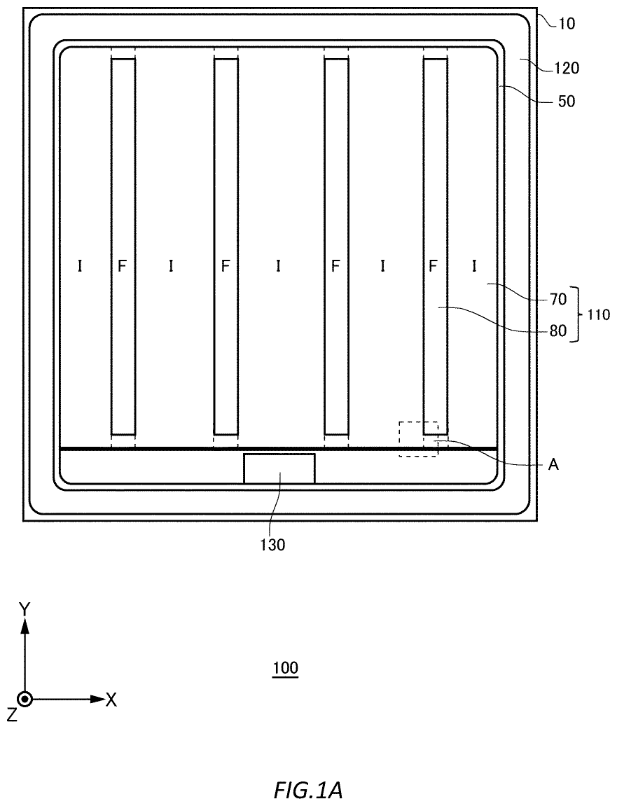

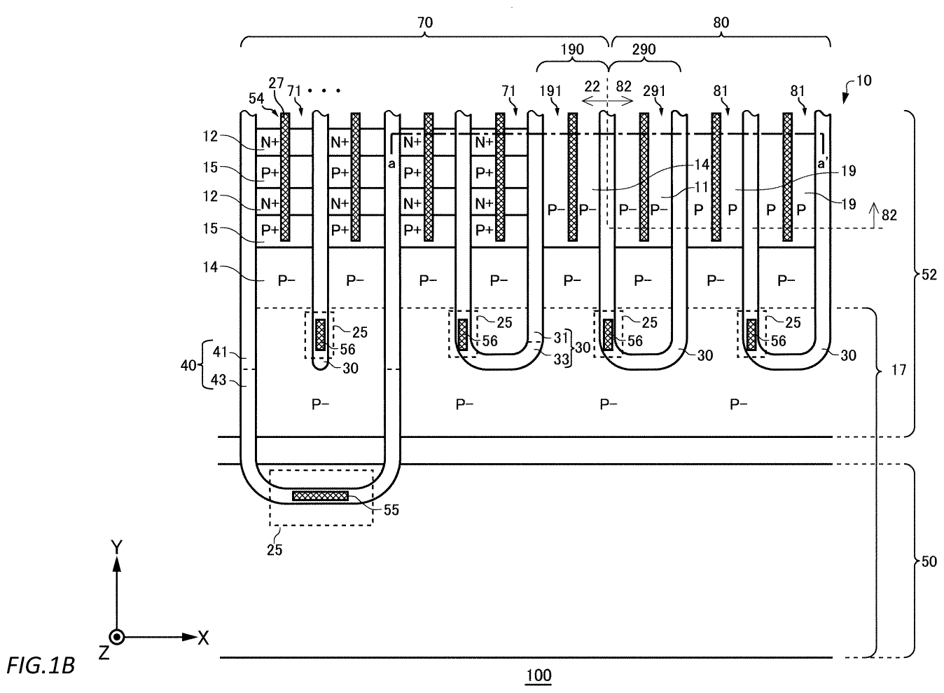

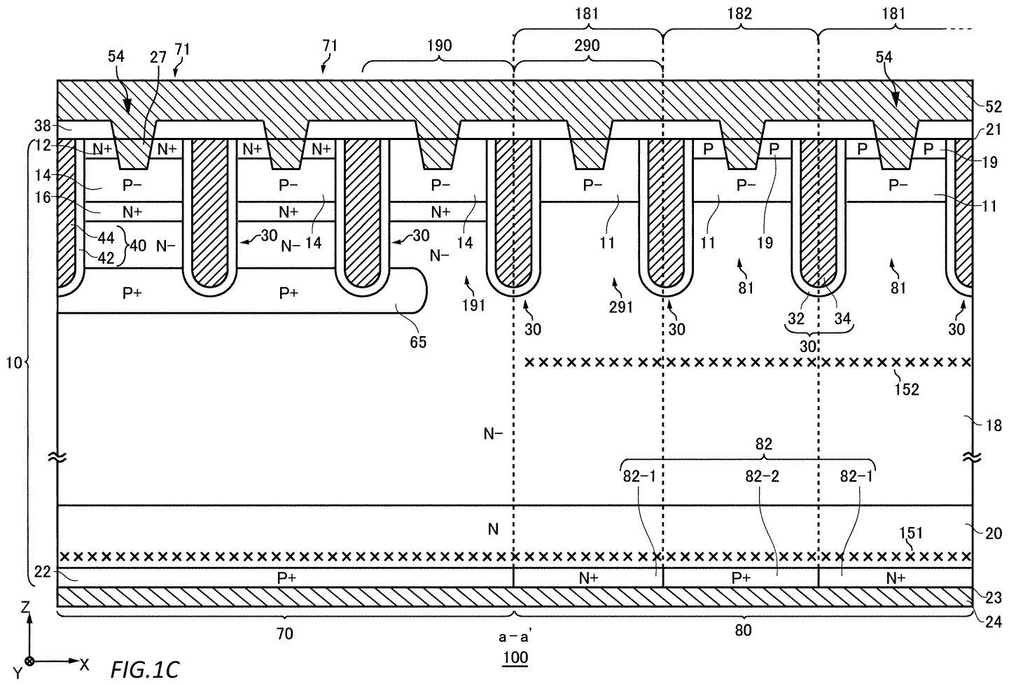

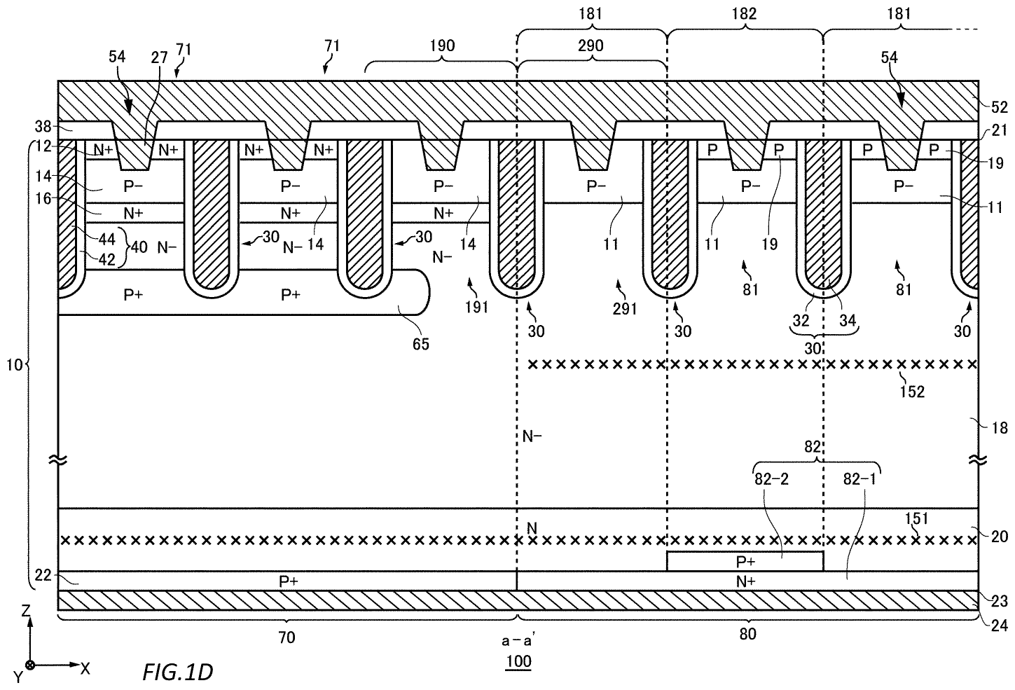

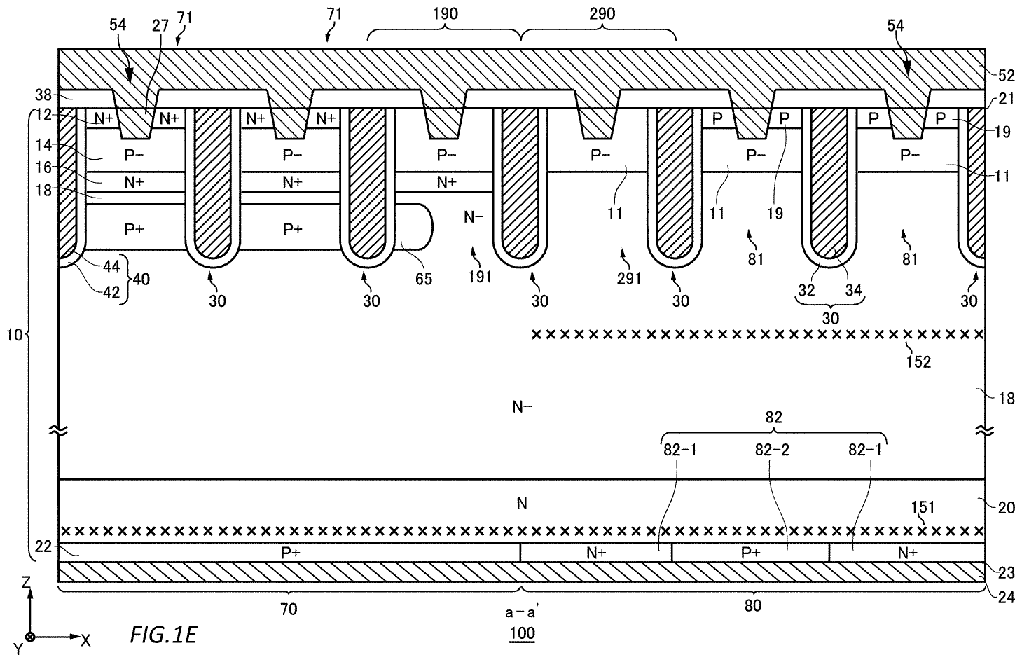

FIG. 1A illustrates an example of a top view of the semiconductor device 100. The semiconductor device 100 is a semiconductor chip including a transistor portion 70 and a diode portion 80.

The transistor portion 70 includes a transistor such as an IGBT (Insulated Gate Bipolar Transistor). The diode portion 80 includes a diode such as a free wheel diode (FWD). The semiconductor device 100 of the present example is a reverse conducting IGBT (RC-IGBT) having the transistor portion 70 and the diode portion 80 on the same chip.

The semiconductor substrate 10 may be a silicon substrate, a silicon carbide substrate, or

a nitride semiconductor substrate such as gallium nitride, or the like. The semiconductor substrate 10 in the present example is the silicon substrate. The semiconductor substrate 10 has an active region 110 and an outer peripheral region 120.

The transistor portion 70 is a region to which a collector region 22 that is described below and provided on a lower surface side of the semiconductor substrate 10 is projected into an upper surface of the semiconductor substrate 10. The diode portion 80 is a region to which a back-surface-side region 82 that is described below and provided on a lower surface side of the semiconductor substrate 10 is projected into the upper surface of the semiconductor substrate 10.

The transistor portion 70 and the diode portion 80 may be arranged alternately in a cyclical manner on the XY plane. The transistor portion 70 and the diode portion 80 of the present example include a plurality of transistor portions and diode portions. In regions among the transistor portions 70 and the diode portions 80, a gate metal layer 50 may be provided above the semiconductor substrate 10.

It is to be noted that the transistor portion 70 and the diode portion 80 of the present example each include a trench portion extending in the Y axis direction. However, the transistor portion 70 and the diode portion 80 may have trench portions that extend in the X axis direction.

The active region 110 has the transistor portion 70 and the diode portion 80. The active region 110 is a region where a principal current flows between the upper surface and lower surface of the semiconductor substrate 10 when the semiconductor device 100 is controlled to be in an ON state. That is, the active region 110 is a region where a current flows inside the semiconductor substrate 10 in the depth direction, from the upper surface to the lower surface or from the lower surface to the upper surface of the semiconductor substrate 10. In the present specification, the transistor portions 70 and the diode portions 80 may be referred to as an element portion or an element region respectively.

Moreover, in a top view, a region sandwiched by two element portions is referred to as an active region 110. In the present example, a region that is sandwiched between the element portions and where the gate metal layer 50 is provided is also included in the active region 110.

The gate metal layer 50 is formed of a material including metal. For example, the gate metal layer 50 is formed of aluminum, aluminum-silicon alloy, or aluminum-silicon-copper alloy. The gate metal layer 50 is electrically connected to a gate conductive portion of the transistor portion 70 and supplies a gate voltage to the transistor portion 70. The gate metal layer 50 is provided to surround the outer circumference of the active region 110 in the top view. The gate metal layer 50 is electrically connected to the gate pad 130 provided in the peripheral region 120. The gate metal layer 50 may be provided along the outer peripheral end of the semiconductor substrate 10. The gate metal layer 50 may include barrier metal formed of titanium, titanium compound, and the like under the region formed of aluminum and the like. Further, the gate metal layer 50 may be provided between the transistor portion 70 and the diode portion 80 in the top view.

In the top view, the outer peripheral region 120 is a region between the active region 110 and the outer peripheral end of the semiconductor substrate 10. The outer peripheral region 120 is, in a top view, provided around the active region 110. One or more metal pads for connecting the semiconductor device 100 and an external device to each other with a wire or the like may be arranged in the peripheral region 120. It is to be noted that the outer peripheral region 120 may include an edge termination structure portion. The edge termination structure portion reduces electric field strength on an upper surface side of the semiconductor substrate 10. For example, the edge termination structure portion has a structure of a guard ring, a field plate, an RESURF, and a combination thereof.

The gate pad 130 is electrically connected to the gate conductive portion of the transistor portion 70 via the gate metal layer 50. The gate pad 130 is set to a gate potential. The gate pad 130 in the present example has a rectangular shape in the top view.

FIG. 1B shows an example of the top view of the semiconductor device 100. In the present example, an enlarged view of a region A in FIG. 1A is shown.

The semiconductor device 100 of the present example includes, in a front surface 21 of the semiconductor substrate 10, a gate trench portion 40, a dummy trench portion 30, an anode region 11, an emitter region 12, a base region 14, first contact region 15, a well region 17, and a second contact region 19. The front surface 21 will be described below. In addition, the semiconductor device 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the anode region 11, the emitter region 12, the base region 14, the first contact region 15, the well region 17, and the second contact region 19. In addition, the gate metal layer 50 is provided above the gate trench portion 40 and the well region 17.

The emitter electrode 52 is formed of a material containing metal. The emitter electrode 52 may be formed of the same material as that of the gate metal layer, or may be formed of a different material. The emitter electrode 52 may include a barrier metal formed of titanium, a titanium compound, or the like under the region formed of aluminum or the like. The emitter electrode 52 and the gate metal layer 50 are provided to be separated from each other.

The emitter electrode 52 and the gate metal layer 50 are provided above the semiconductor substrate 10 with an interlayer dielectric film 38 interposed therebetween. The interlayer dielectric film 38 is omitted in FIG. 1B. A contact hole 54, a contact hole 55, and a contact hole 56 are provided to penetrate the interlayer dielectric film 38.

The contact holes 55 connect the gate metal layer 50 and the gate conductive portions inside the transistor portions 70. Inside the contact hole 55, a plug formed of tungsten or the like may be formed.

The contact hole 56 connects the emitter electrode 52 with a dummy conductive portion within the dummy trench portion 30. Inside the contact hole 56, a plug formed of tungsten or the like may be formed.

A connecting portion 25 electrically connects an electrode on the side of the front surface such as the emitter electrode 52 or the gate metal layer 50 to the semiconductor substrate 10. In an example, the connecting portion 25 is provided between the gate metal layer 50 and the gate conductive portion. The connecting portion 25 is also provided between the emitter electrode 52 and the dummy conductive portion. The connecting portion 25 is a conductive material such as polysilicon doped with impurities. Here, the connecting portion 25 is formed of polysilicon (N+) doped with the impurities of the N type. The connecting portion 25 is provided above the front surface 21 of the semiconductor substrate 10 via a dielectric film such as an oxide film, or the like.

The gate trench portion 40 is an example of a plurality of trench portions extending in a predetermined trench extending direction on a front surface 21 side of the semiconductor substrate 10. The gate trench portions 40 are arrayed at a predetermined interval along a predetermined array direction (the X axis direction in the present example). The gate trench portion 40 in the present example may include two extending parts 41 which extend along an extending direction (the Y axis direction in the present example) parallel to the front surface 21 of the semiconductor substrate 10 and perpendicular to the array direction, and a connecting part 43 which connects the two extending parts 41.

At least a part of the connecting part 43 is preferably formed in a curved shape.

Connecting end portions of the two extending parts 41 of the gate trench portion 40 can reduce electric field strength at the end portions of the extending parts 41. At the connecting part 43 of the gate trench portion 40, the gate metal layer 50 may be connected to the gate conductive portion.

The dummy trench portion 30 is a trench portion electrically connected to the emitter electrode 52. Similarly to the gate trench portions 40, the dummy trench portions 30 are arrayed at a predetermined interval along a predetermined array direction (the X axis direction in the present example). The dummy trench portion 30 in the present example may have, similarly to the gate trench portion 40, a U shape on the front surface 21 of the semiconductor substrate 10. That is, the dummy trench portion 30 may have two extending parts 31 which extend along the extending direction and a connecting part 33 which connects the two extending parts 31.

The transistor portion 70 in the present example has a repetitive array structure of two gate trench portions 40 and three dummy trench portions 30. That is, the transistor portion 70 in the present example includes the gate trench portions 40 and the dummy trench portions 30 at a ratio of 2:3. For example, the transistor portion 70 includes one extending part 31 between two extending parts 41. In addition, the transistor portion 70 includes two extending parts 31 adjacent to the gate trench portion 40.

It is to be noted that the ratio between the gate trench portions 40 and the dummy trench portions 30 is not limited to that in the present example. The ratio of the gate trench portions 40 and the dummy trench portions 30 may be 1:1 or may be 2:4. Also, the transistor portion 70 may have a namely full gate configuration where the gate trench portions 40 are all provided, without any of the dummy trench portion 30.

The well region 17 is a region of a second conductivity type which is provided on a front surface 21 side of the semiconductor substrate 10 relative to a drift region 18 to described below. The well region 17 is an example of the well region provided in the edge side of the semiconductor device 100. The well region 17 is of the P+ type as an example. The well region 17 is formed within a predetermined range from an end portion of an active region on a side where the gate metal layer 50 is provided. A diffusion depth of the well region 17 may be deeper than a depth of the gate trench portion 40 and the dummy trench portion 30. Partial regions of the gate trench portion 40 and the dummy trench portion 30 on a gate metal layer 50 side are formed in the well region 17. Bottoms of ends in the extending direction of the gate trench portion 40 and the dummy trench portion 30 may be covered with the well region 17.

In the transistor portion 70, the contact hole 54 is formed above each region of the emitter region 12, the base region 14, and the first contact region 15. In addition, in the diode portion 80, the contact hole 54 is provided above the anode region 11 and the second contact region 19. The contact hole 54 is provided above the base region 14 in the diode portion 80. No contact holes 54 are provided above the well regions 17 provided at both ends in the Y axis direction. In this manner, one or more contact holes 54 are formed in the interlayer dielectric film. The one or more contact holes 54 may be provided to extend in an extending direction.

A trench contact portion 27 electrically connects the emitter electrode 52 and the semiconductor substrate 10. The trench contact portion 27 is provided in the contact hole 54. The trench contact portion 27 is provided to extend in the extending direction.

The first boundary portion 190 is a region that is provided in the transistor portion 70 and is adjacent to the diode portion 80. The first boundary portion 190 may have the base region 14. The first boundary portion 190 may not have any of the emitter region 12 or the first contact region 15. In an example, the trench portion of the first boundary portion 190 is the dummy trench portion 30. The first boundary portion 190 of the present example is arranged such that both ends in the X axis direction are dummy trench portions 30.

The second boundary portion 290 is a region that is provided in the diode portion 80 and is adjacent to the transistor portion 70. The second boundary portion 290 has the anode region 11. The second boundary portion 290 does not have the second contact region 19. In an example, the trench portion of the second boundary portion 290 is the dummy trench portion 30. The second boundary portion 290 of the present example is arranged such that both ends in the X axis direction are dummy trench portions 30.

A mesa portion 71, a mesa portion 81, a mesa portion 191, a mesa portion 291 are mesa portions provided to be adjacent to the trench portion in a surface that is parallel to the front surface 21 of the semiconductor substrate 10. The mesa portion may be a part of the semiconductor substrate 10 sandwiched between two trench portions adjacent to each other, and may be a part from the front surface 21 of the semiconductor substrate 10 to a depth of a lowermost bottom portion of each trench portion. The extending part of each trench portion may be defined as one trench portion. That is, a region sandwiched between two extending parts may be defined as a mesa portion.

The mesa portion 71 is provided adjacent to at least one of the dummy trench portion 30 or the gate trench portion 40 in the transistor portion 70. The mesa portion 71 has the well region 17, the emitter region 12, the base region 14, and the first contact region 15 on the front surface 21 of the semiconductor substrate 10. In the mesa portion 71, the emitter region 12 and the first contact region 15 are provided alternately in the extending direction.

The mesa portion 81 is provided in a region sandwiched between adjacent dummy trench portions 30 in the diode portion 80. The mesa portion 81 has a second contact region 19 on the front surface 21 of the semiconductor substrate 10. The mesa portion 81 in this example has the base region 14 and the well region 17 on the negative side in the Y axis direction.

The mesa portion 191 is provided in the first boundary portion 190. The mesa portion 191 includes the base region 14 at the front surface 21 of the semiconductor substrate 10. The mesa portion 191 of the present example has the base region 14 and the well region 17 at the negative side of the Y axis direction.

The mesa portion 291 is provided in the second boundary portion 290. The mesa portion 291 has the anode region 11 at the front surface 21 of the semiconductor substrate 10. The mesa portion 291 of the present example has the base region 14 and the well region 17 at the negative side of the Y axis direction.

The anode region 11 is a region of a second conductivity type that is provided on a front surface 21 side of the semiconductor substrate 10 in the diode portion 80. The anode region 11 is of the P-type as an example. The anode region 11 may be formed with the same dopant as that of the base region 14, or may be formed with a different dopant. A doping concentration of the anode region 11 may be the same as, or may be different from the doping concentration of the base region 14.

The base region 14 is a region of second conductivity type provided in the transistor portion 70 and the diode portion 80 on the side of the front surface 21 of the semiconductor substrate 10. The base region 14 is of the P-type as an example. The base region 14 may be provided at both end portions in the Y axis direction of the mesa portion 71, the mesa portion 81, the mesa portion 191, and the mesa portion 291 on the front surface 21 of the semiconductor substrate 10. Note that FIG. 1B shows only one end of the base region 14 in the Y axis direction.

The emitter region 12 is a region of a first conductivity type which has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71. The emitter region 12 is also provided below the contact hole 54.

In addition, the emitter region 12 may or may not be in contact with the dummy trench portion 30. The emitter region 12 in the present example is in contact with the dummy trench portion 30. The emitter region 12 may not be provided in the mesa portion 81, the mesa portion 191, and the mesa portion 291.

The first contact region 15 is a region of the second conductivity type having a higher doping concentration than the base region 14. The first contact region 15 in the present example is of the P+ type as an example. The first contact region 15 in the present example is provided at the front surface 21 of the mesa portion 71.

The first contact region 15 may be provided in the X axis direction from one to another of two trench portions sandwiching the mesa portion 71. The first contact region 15 may or may not be in contact with the gate trench portion 40. Also, the first contact region 15 may or may not be in contact with the dummy trench portion 30. In the present example, the first contact region 15 may be in contact with the dummy trench portion 30 and the gate trench portion 40. The first contact region 15 may also be provided below the contact hole 54.

The second contact region 19 is a region the second conductivity type having a higher doping concentration than that of the anode region 11. The second contact region 19 of the present example is, for example, of the P type. The doping concentration of the second contact region 19 may be the same as, or may be different from the doping concentration of the first contact region 15. The doping concentration of the second contact region 19 of the present example is lower than the doping concentration of the first contact region 15. The second contact region 19 in the present example is provided at the front surface 21 of the mesa portion 81.

The second contact region 19 may be provided in the X axis direction from one to another of two trench portions sandwiching the mesa portion 81. The second contact region 19 may or may not be in contact with the dummy trench portion 30. In the present example, the second contact region 19 is in contact with the dummy trench portion 30. The second contact region 19 may also be provided below the contact hole 54.

FIG. 1C is a view showing one example of the cross section a-a′ in FIG. 1B. The cross section a-a′ is an XZ plane which passes through the emitter region 12 in the transistor portion 70. The semiconductor device 100 of the present example has a semiconductor substrate 10 including an accumulation region 16 and a trench bottom region 65, an interlayer dielectric film 38, an emitter electrode 52, and a collector electrode 24 in the cross section a-a′. The emitter electrode 52 is formed above the semiconductor substrate 10 and the interlayer dielectric film 38.

The drift region 18 is a region of the first conductivity type which is provided in the semiconductor substrate 10. The drift region 18 of the present example is of the N-type, as an example. The drift region 18 may be a region in the semiconductor substrate 10 which has remained without other doping regions formed. That is, a doping concentration of the drift region 18 may be a doping concentration of the semiconductor substrate 10.

A buffer region 20 is a region of the first conductivity type provided below the drift region 18. The buffer region 20 in the present example is of the N type as an example. A doping concentration of the buffer region 20 is higher than the doping concentration of the drift region 18. The buffer region 20 may function as a field stop layer to prevent a depletion layer expanded from the lower surface side of the base region 14 from reaching the collector region 22 of the second conductivity type and the back-surface-side region 82 of the first conductivity type.

The collector region 22 is provided below the drift region 18 in the transistor portion 70. The collector region 22 is of the second conductivity type. The collector region 22 is, for example, of the P+ type.

The back-surface-side region 82 is provided below the drift region 18 in the diode portion 80. The back-surface-side region 82 of the present example has a first conductivity type portion 82-1 and a second conductivity type portion 82-2. The boundary between the collector region 22 and the back-surface-side region 82 is the boundary of the transistor portion 70 and the diode portion 80.

The first conductivity type portion 82-1 is a region of the first conductivity type that has a doping concentration higher than that of the drift region 18. The first conductivity type portion 82-1 of the present example is provided to be in contact with the back surface 23 of the semiconductor substrate 10. The doping concentration of the first conductivity type portion 82-1 may be higher than the doping concentration of the buffer region 20. The doping concentration of the first conductivity type portion 82-1 may be 1E15 cm⁻³ or more, and 1E21 cm⁻³ or less. In an example, the first conductivity type portion 82-1 is of the N+ type.

The second conductivity type portion 82-2 is a region of the second conductivity type having a higher doping concentration than the base region 14. The doping concentration of the second conductivity type portion 82-2 may be 1E16 cm⁻³ or more, and 1E21 cm⁻³ or less. In an example, the second conductivity type portion 82-2 is of the P+ type. The doping concentration of the second conductivity type portion 82-2 may be the same as or may be different from the doping concentration of the collector region 22. The second conductivity type portion 82-2 of the present example is provided to be in contact with the back surface 23 of the semiconductor substrate 10 and to be adjacent to the first conductivity type portion 82-1. The second conductivity type portion 82-2 may be in direct contact with the first conductivity type portion 82-1.

The first conductivity type portion 82-1 may be formed, by an ion implanting for forming the second conductivity type portion 82-2, by performing an ion implantation of a P type dopant, and then further performing an implantation of an N type dopant. On the contrary, the second conductivity type portion 82-2 may be formed, by an ion implanting for forming the first conductivity type portion 82-1, by performing an ion implantation of an N type dopant, and then further performing implantation of a P type dopant.

The first conductivity type portion 82-1 and the second conductivity type portion 82-2 are provided such that a repetitive structure is formed, in which a second conductivity type non-forming region 181 and a second conductivity type forming region 182 are alternately and repeatedly arrayed in a predetermined direction. The second conductivity type non-forming region 181 is a region in which the second conductivity type portion 82-2 is not formed on a back surface 23 side of the semiconductor substrate 10 in a top view. The second conductivity type forming region 182 is a region in which the second conductivity type portion 82-2 is formed on the back surface 23 side of the semiconductor substrate 10 in a top view.

The second conductivity type non-forming region 181 and the second conductivity type forming region 182 may be arrayed alternately in a trench array direction (for example, the X axis direction), or may be arrayed alternately in a trench extending direction (for example, the Y axis direction). The second conductivity type non-forming region 181 and the second conductivity type forming region 182 may be arranged in a stripe shape in a top view. Thereby, the forward voltage Vf of the diode portion 80 can be reduced. Details of the array of the second conductivity type non-forming region 181 and the second conductivity type forming region 182 will be described below.

In the second boundary portion 290, the back surface 23 of the semiconductor substrate 10 has the first conductivity type portion 82-1. By providing the first conductivity type portion 82-1 to the back surface 23 of the second boundary portion 290, the current at the time of switching of the semiconductor device 100 is equalized, and the switching efficiency is improved. The collector electrode 24 is formed on the back surface 23 of the semiconductor

substrate 10. The collector electrode 24 is formed of a conductive material such as metal. The material of the collector electrode 24 may be the same as or may be different from the material of the emitter electrode 52 and the gate metal layer 50.

An accumulation region 16 is a region of the first conductivity type which is provided on the front surface 21 side of the semiconductor substrate 10 relative to the drift region 18. The accumulation region 16 in the present example is of the N+ type, as an example. The accumulation region 16 is provided in the transistor portion 70. It is to be noted that the accumulation region 16 may not be provided.

In addition, the accumulation region 16 is provided in contact with the gate trench portion 40. The accumulation region 16 may or may not be in contact with the dummy trench portion 30. A doping concentration of the accumulation region 16 is higher than the doping concentration of the drift region 18. Providing the accumulation region 16 can increase a carrier injection enhancement effect (IE effect) to reduce an on-voltage of the transistor portion 70.

The interlayer dielectric film 38 is provided at the front surface 21. The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 55 and contact holes 56 may be provided penetrating the interlayer dielectric film 38.

The trench contact portion 27 contains a conductive material filled in the contact hole 54. The trench contact portion 27 is provided between two adjacent trench portions among a plurality of trench portions. The trench contact portion 27 of the present example is provided to pass through from the front surface 21 to the emitter region 12. The trench contact portion 27 may contain the same material as that of the emitter electrode 52.

The lower end of the trench contact portion 27 is positioned deeper than the position of the lower end of the emitter region 12. By providing the trench contact portion 27, the resistance of the base region 14 is reduced, and the extraction of the minority carriers (for example, holes) becomes easier. This can improve the breakdown withstand capability such as a latch up withstand capability due to minority carriers.

The trench contact portion 27 has a bottom surface with a substantially planar shape. The bottom surface of the trench contact portion 27 may be covered with a plug layer and the like of the second conductivity type. The trench contact portion 27 of the present example is in a tapered shape with inclined side walls. Note that, the side wall of the trench contact portion 27 may be provided so as to be substantially perpendicular to the front surface 21.

One or more gate trench portions 40 and one or more dummy trench portions 30 are provided at the front surface 21. Each trench portion is provided from the front surface 21 to the drift region 18. For regions in which at least any of the anode region 11, the emitter region 12, the base region 14, the first contact region 15, the accumulation region 16, or the second contact region 19 is provided, each trench portion passes through these regions to reach the drift region 18.

A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

The gate trench portion 40 includes a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside the gate dielectric film 42 within the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a mesa portion 71 side with the gate dielectric film 42 interposed therebetween, in the depth direction of the semiconductor substrate 10. When a predetermined voltage is applied to the gate conductive portion 44, a channel with an electron inversion layer is formed in a surface layer of an interface of the base region 14 which is in contact with the gate trench.

The dummy trench portion 30 may have the same structure as that of the gate trench portion 40. The dummy trench portion 30 includes a dummy trench, a dummy dielectric film 32, and a dummy conductive portion 34 which are formed on the front surface 21 side. The dummy dielectric film 32 is formed to cover an inner wall of the dummy trench. The dummy conductive portion 34 is formed within the dummy trench, and is formed inside the dummy dielectric film 32. The dummy dielectric film 32 insulates the dummy conductive portion 34 from the semiconductor substrate 10. The dummy trench portion 30 is covered with the interlayer dielectric film 38 at the front surface 21.

The trench bottom region 65 is a region of the second conductivity type that is provided below the base region 14. A doping concentration in the trench bottom region 65 in the present example is higher than the doping concentration in the base region 14. The trench bottom region 65 of the present example is of a P+ type as an example. The doping concentration of the trench bottom region 65 may be 1E14 cm⁻³ or more and 1E18 cm 3 or less. By forming the trench bottom region 65, the ON loss Eon of the semiconductor device 100 can be reduced.

The trench bottom region 65 of the present example is provided such that the upper end is not in contact with the accumulation region 16. That is, in the depth direction of the semiconductor substrate 10, the drift region 18 is formed between the trench bottom region 65 and the accumulation region 16. The trench bottom region 65 may be provided such that the upper end is in contact with the lower end of the accumulation region 16.

The trench bottom region 65 in this example is provided to extend from the lower end of one trench portion among a plurality of trench portions to the lower end of opposing another trench portion in the trench array direction of the plurality of trench portions. The trench bottom region 65 may be provided to extend from the lower end of one trench portion among the plurality of trench portions beyond the lower end of the opposing another trench portion to the lower end of the trench portion in direct contact with the opposing another trench portion. That is, the trench bottom region 65 may be provided extending beyond lower ends of a plurality of trench portions, a number of which is two or more.

The first lifetime control region 151 is provided in the diode portion 80. Thereby, the semiconductor device 100 of the present example can reduce the switching loss by speeding up the recovery in the diode portion 80. The first lifetime control region 151 may be provided in the transistor portion 70.

The first lifetime control region 151 may be formed by implanting impurity from the front surface 21 side, or may be formed by implanting impurity from the back surface 23 side. The first lifetime control region 151 may be formed by performing an ion implantation of helium into the semiconductor substrate 10.

The second lifetime control region 152 is provided on the front surface 21 side relative to a center of the semiconductor substrate 10 in the depth direction of the semiconductor substrate 10. The second lifetime control region 152 in this example is provided in the drift region 18. The second lifetime control region 152 is provided in both the transistor portion 70 and the diode portion 80. The second lifetime control region 152 may be formed by implanting an impurity from the front surface 21 side, or may be formed by implanting an impurity from the back surface 23 side. The second lifetime control region 152 is provided in the diode portion 80, the first boundary portion 190, and the second boundary portion 290, and may not be provided in a part of the transistor portion 70.

The second lifetime control region 152 may be formed by any method among methods for forming the first lifetime control region 151. An element, a dose amount, and the like for forming the first lifetime control region 151 may be the same as or different from those for forming the second lifetime control region 152.

FIG. 1D shows a modified example of the cross section a-a′ in FIG. 1B. By using FIG. 1D, differences from FIG. 1C will be described.

In the present example, the first conductivity type portion 82-1 is provided on the back surface 23 of the semiconductor substrate 10. The first conductivity type portion 82-1 may function as the diode portion 80.

In the present example, the second conductivity type portion 82-2 is provided above the first conductivity type portion 82-1. The second conductivity type portion 82-2 of the present example is provided to be in contact with the first conductivity type portion 82-1, but is not limited thereto. The second conductivity type portion 82-2 may be provided to be spaced apart from the first conductivity type portion 82-1.

The second conductivity type portion 82-2 of the present example has the same thickness as that of the first conductivity type portion 82-1. The second conductivity type portion 82-2 may be thinner than the first conductivity type portion 82-1. The second conductivity type portion 82-2 may have a thickness smaller than or equal to the length from the upper end of the first conductivity type portion 82-1 to the lower end of the first lifetime control region 151.

The second conductivity type portion 82-2 of the present example is provided closer to the back surface 23 side of the semiconductor substrate 10 than the first lifetime control region 151.

The second conductivity type portion 82-2 may be provided closer to the front surface 21 side of the semiconductor substrate 10 than the first lifetime control region 151.

The second conductivity type non-forming region 181 is a region in which the second conductivity type portion 82-2 is not formed on a back surface 23 side of the semiconductor substrate 10 in a top view. The second conductivity type forming region 182 is a region in which the second conductivity type portion 82-2 is formed on the back surface 23 side of the semiconductor substrate 10 in a top view. As in the present example, even if the second conductivity type portion 82-2 is formed above the first conductivity type portion 82-1, a repetitive structure can be formed, in which the second conductivity type non-forming region 181 and the second conductivity type forming region 182 are alternately and repeatedly arrayed in a top view.

FIG. 1E shows a modified example of the cross section a-a′ in FIG. 1B. By using FIG. 1E, differences from FIG. 1C will be described.

In the example of FIG. 1E, the depth position at the lower end of the trench bottom region 65 is provided closer to the front surface 21 side than the depth position of the trench bottom portion among the plurality of trench portions. The trench bottom region 65 is provided to have a depth position of the upper end that is deeper than the base region 14. The trench bottom region 65 may be provided to have a depth position of the upper end that is deeper than the accumulation region 16. The drift region 18 may be provided between the trench bottom region 65 and the accumulation region 16.

The trench bottom region 65 is provided to have a depth position of its lower end that is a position shallower than the depth position of the lower ends of the gate trench portion 40 and the dummy trench portion 30. That is, the trench bottom region 65 may not cover the trench bottom portions of the gate trench portion 40 and the dummy trench portion 30. Even in such a case, it is possible to increase the gate capacitance of the transistor portion 70, and reduce the ON loss Eon of the semiconductor device 100.

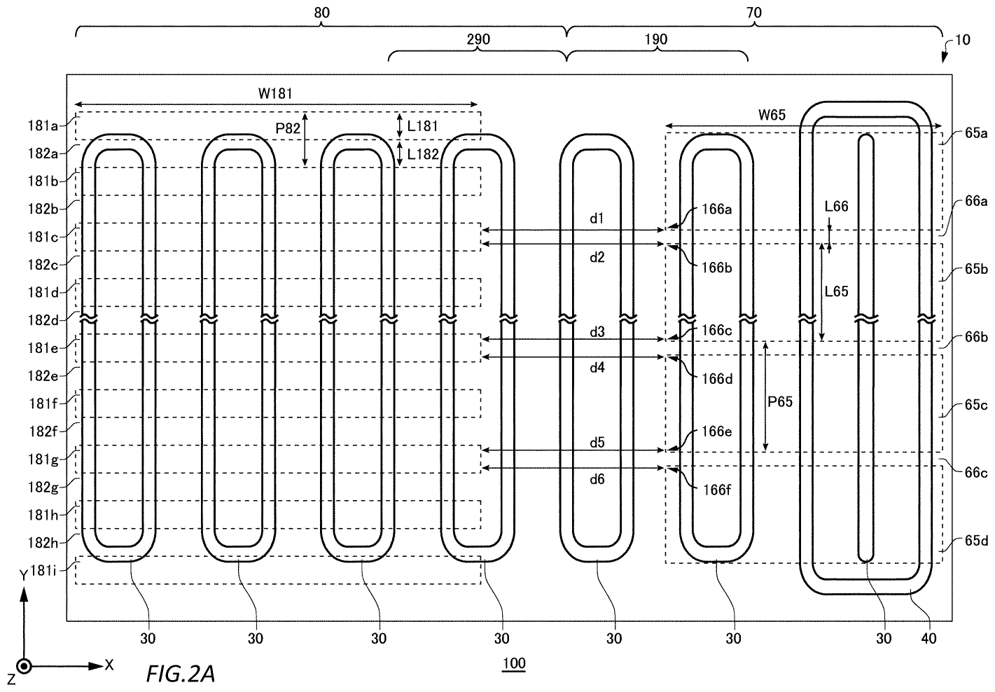

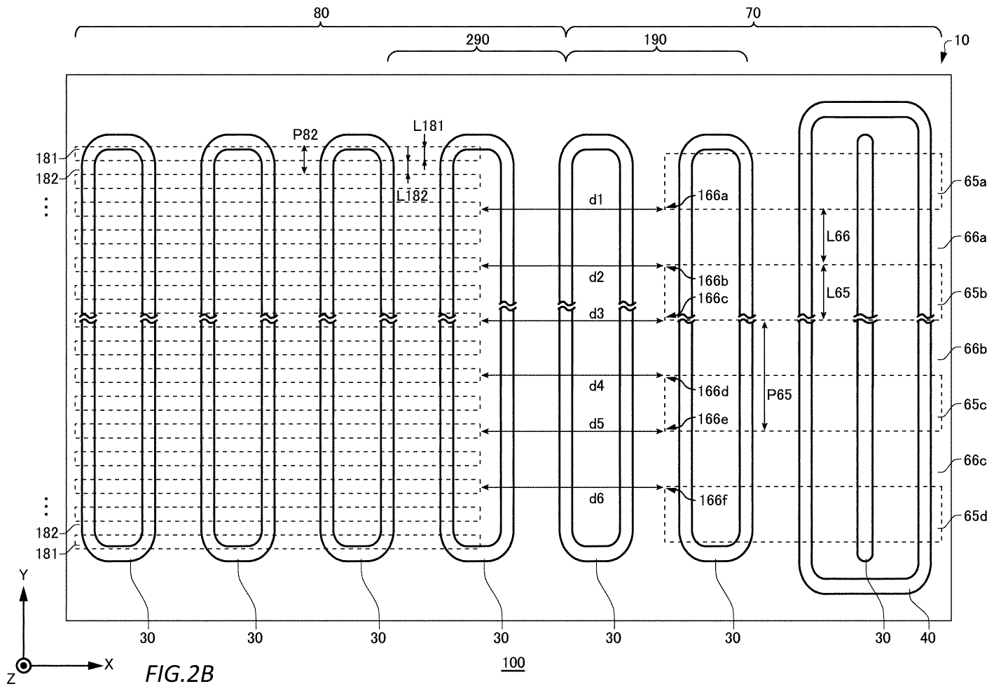

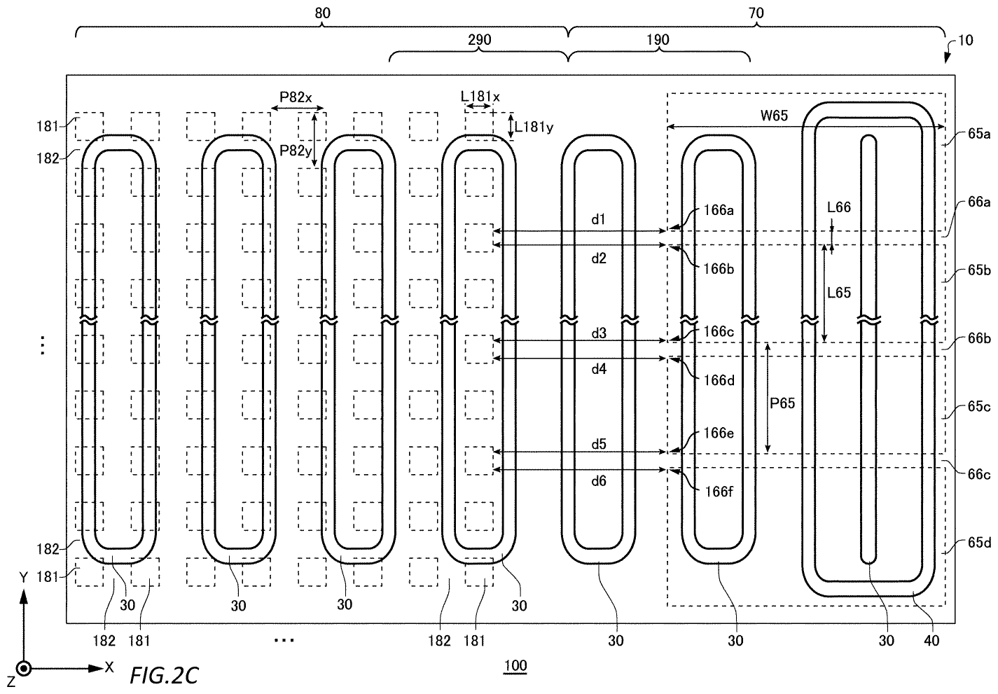

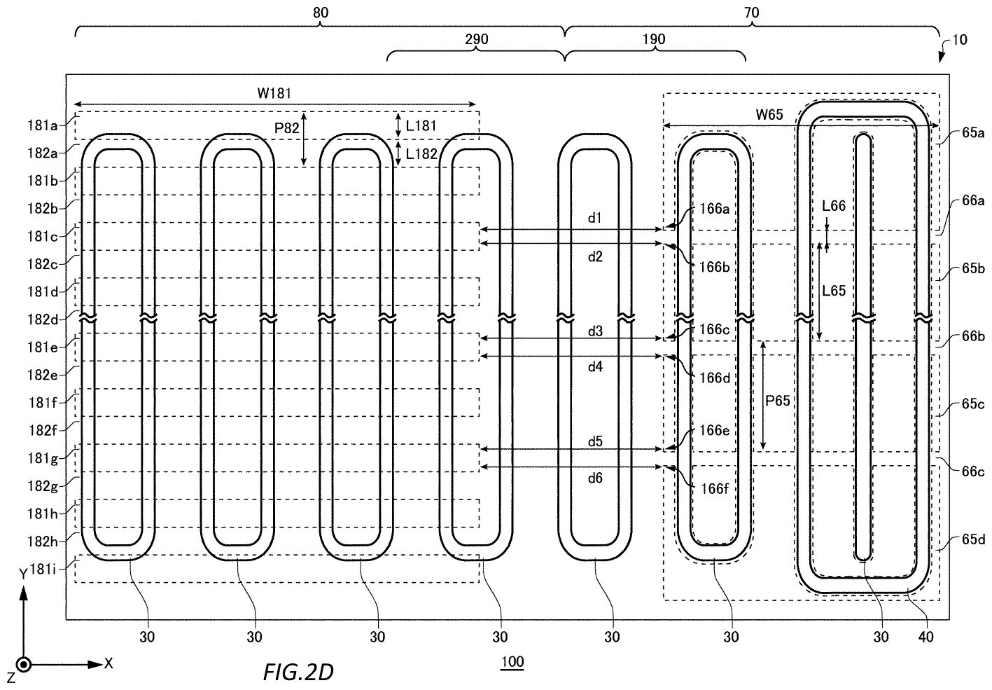

FIG. 2A shows an example of the top view of the semiconductor device 100. By using FIG. 2A, the position relationship between the trench bottom region 65 in the semiconductor device 100 of the present example and the second conductivity type non-forming region 181 and the second conductivity type forming region 182 will be described. In the following figure, for simplicity, only components that are required to be described will be illustrated, and the other components will be omitted.

The transistor portion 70 has a plurality of trench bottom regions 65 provided repeatedly in a trench extending direction of the plurality of trench portions (in the present example, the Y axis direction). The transistor portion 70 is provided repeatedly in the trench extending direction, and has a plurality of trench bottomless regions 66 sandwiched between a plurality of trench bottom regions 65. The trench bottom region 65 and the trench bottomless region 66 are provided to extend from the transistor portion 70 toward the diode portion 80 in the trench array direction, and terminate at the first boundary portion 190 without reaching the diode portion 80.

The width W65 of the trench bottom region 65 in the trench array direction may be the same as the width of the transistor portion 70 in the trench array direction, or may be smaller than the width of the transistor portion 70 in the trench array direction. The trench bottom region 65 may be provided to extend from one end of the transistor portion 70 in the trench array direction to another end.

The plurality of trench bottom regions 65 is repeatedly arranged in a predetermined trench bottom repetition period P65. The trench bottom repetition period P65 may be a distance from one end of one trench bottom region 65 in the trench extending direction to an adjacent trench bottom region 65 beyond another end of the trench bottom region. In an example, the trench bottom repetition period P65 is a distance from an end side of a trench bottom region 65b at the negative side of the Y axis to an end side of a trench bottom region 65c at the negative side of the Y axis.

The trench bottom repetition period P65 is greater than a back-surface-side repetition period P82 described below. The trench bottom repetition period P65 may be an integer multiple of the back-surface-side repetition period P82. In an example, the trench bottom repetition period P65 is 5 μm or more, and 200 μm or less.

In a top view, the area of the trench bottom region 65 is greater than the area of the trench bottomless region 66. In an example, in one trench bottom repetition period P65, the width L65 of the trench bottom region 65 in the trench extending direction is greater than the width L66 of the trench bottomless region 66 in the trench extending direction. In an example, in one trench bottom repetition period P65, the width L65 of the trench bottom region 65 in the trench extending direction one time or more or ten times or less, of the width L66 of the trench bottomless region 66. Also, the width L65 of the trench bottom region 65 in the trench extending direction may be greater than the width L181 of the second conductivity type non-forming region 181 in the trench extending direction, or may be greater than the width L182 of the second conductivity type forming region 182 in the trench extending direction.

Areas of the plurality of trench bottomless regions 66 sandwiched between the plurality of trench bottom regions 65 may be substantially the same to each other. In an example, each area of the plurality of trench bottomless regions 66 sandwiched between the plurality of trench bottom regions 65 is 85% or more and 115% or less of each predetermined reference value. As an example, the area of the trench bottomless region 66a in a top view is the same as the area of the trench bottomless region 66b. By making respective areas of the plurality of trench bottomless regions 66 uniform, the magnitude of the electron current flowing at the time of switching on of the semiconductor device 100 can be equalized.

The predetermined reference value may be the area of any trench bottomless region 66 among the areas of the plurality of trench bottomless regions 66. The predetermined reference value may be an average value, a minimum value, or a maximum value of the area of the plurality of trench bottomless regions 66.

In the diode portion 80, the second conductivity type non-forming region 181 and the second conductivity type forming region 182 are provided. In the example of FIG. 2A, the second conductivity type non-forming region 181 and the second conductivity type forming region 182 extend in the trench array direction (in the present example, the X axis direction) and are arranged alternately in the trench extending direction. The second conductivity type non-forming region 181 and the second conductivity type forming region 182 are provided to extend from the diode portion 80 toward the transistor portion 70 in the trench array direction, and terminate at the second boundary portion 290 without reaching the transistor portion 70.

The width W181 of the second conductivity type non-forming region 181 in the trench array direction may be the same as the width of the diode portion 80 in the trench array direction, or may be smaller than the width of the diode portion 80 in the trench array direction. The second conductivity type non-forming region 181 may be provided to extend from one end of the diode portion 80 in the trench array direction to another end.

The second conductivity type non-forming region 181 and the second conductivity type forming region 182 are arranged alternately in a predetermined back-surface-side repetition period P82. The back-surface-side repetition period P82 may be a distance from one end of one second conductivity type non-forming region 181 in the trench extending direction to an adjacent second conductivity type non-forming region 181 beyond another end of the second conductivity type non-forming region 181. In an example, the back-surface-side repetition period P82 is a distance from an end side of the second conductivity type non-forming region 181a on the positive side of the Y axis to an end side of the second conductivity type non-forming region 181b on the positive side of the Y axis.

The back-surface-side repetition period P82 is smaller than the trench bottom repetition period P65. The back-surface-side repetition period P82 may be 20 μm, 30 μm, or 50 μm. In an example, the back-surface-side repetition period P82 is 10 μm or more and 100 μm or less.

The second conductivity type non-forming region 181 and the second conductivity type forming region 182 may be arranged alternately in the trench extending direction or may be arranged alternately in the trench array direction. In the example shown in FIG. 2A, the second conductivity type non-forming region 181 and the second conductivity type forming region 182 extend in the trench array direction and are arranged alternately in the trench extending direction. By alternately arranging the second conductivity type non-forming region 181 and the second conductivity type forming region 182 in the trench extending direction, the alignment at the time of fabricating the semiconductor device 100 becomes easy, and the variation in the characteristics of the semiconductor device 100 can be reduced.

In the example of FIG. 2A, in each back-surface-side repetition period P82, the area of the second conductivity type non-forming region 181 and the area of the second conductivity type forming region 182 are the same. In the example of FIG. 2A, the area of the second conductivity type non-forming region 181a and the area of the second conductivity type forming region 182a are the same.

In the back-surface-side repetition period P82, the area of the second conductivity type non-forming region 181 and the area of the second conductivity type forming region 182 may be different. In one back-surface-side repetition period P82, the width L181 of the second conductivity type non-forming region 181 in the trench extending direction may be different from the width L182 of the second conductivity type forming region in the trench extending direction.

In an example, the width L181 of the second conductivity type non-forming region 181 in the trench extending direction is 30% or more and 70% or less of the sum of the width L181 of the second conductivity type non-forming region 181 and the width L182 of the second conductivity type forming region 182 in the trench extending direction. That is, the area of the second conductivity type non-forming region 181 may be 30% or more and 70% or less of the area of the back-surface-side region 82. Due to the difference between the width L181 of the second conductivity type non-forming region 181 in the trench extending direction and the width L182 of the second conductivity type forming region 182 in the trench extending direction, equalizing of the electron current at the time of the semiconductor device 100 is turned on becomes easier.

In a top view, the shortest distance from each of the end portions 166 of the plurality of trench bottomless regions 66 to the second conductivity type non-forming region 181 is 85% or more and 115% or less of a predetermined reference value. Each of the end portions 166 of the plurality of trench bottomless regions 66 of the present example is a corner portion of the trench bottomless region 66.

The predetermined reference value may be the shortest distance from any end portion 166 among the plurality of end portions 166 to the second conductivity type non-forming region 181. The predetermined reference value may be an average value, a minimum value, or a maximum value of each shortest distance from the plurality of end portions 166 to the second conductivity type non-forming region 181.

In the example shown in FIG. 2A, the shortest distance from the end portion 166a of the trench bottomless region 66a on the positive side of the Y axis to the second conductivity type non-forming region 181c is indicated as d1. Also, d2 to d6 are shortest distances from the end portion 166b of the trench bottomless region 66a, the end portion 166c and the end portion 166d of the trench bottomless region 66b, and the end portion 166e and the end portion 166f of the trench bottomless region 66c to the second conductivity type non-forming region 181. All of the shortest distances d1 to d6 from the respective end portions 166 of the plurality of trench bottomless regions 66 to the plurality of second conductivity type non-forming regions 181 are substantially the same. In the present example, for each of the plurality of trench bottomless regions 66, a distance from each end portion 166 of each trench bottomless region 66 to the second conductivity type non-forming region 181 is equalized. Thereby, the electron current flowing at the time of switching on of the semiconductor device 100 can be equalized, and the ON loss Eon can be reduced.

In the trench array direction of the plurality of trench portions, each of the plurality of trench bottomless regions 66 is facing any of the plurality of second conductivity type non-forming regions 181. In the example shown in FIG. 2A, the trench bottomless region 66a is facing the second conductivity type non-forming region 181c, the trench bottomless region 66b is facing the second conductivity type non-forming region 181e, and the trench bottomless region 66c is facing the second conductivity type non-forming region 181g. By arranging in this manner, the length of the path through which the electron current that flows at the time of the switching on of the semiconductor device 100 is flowing can be equalized in each trench bottomless region 66, to reduce the ON loss Eon.

The second conductivity type non-forming region 181 and the second conductivity type forming region 182 may be provided to be line symmetric with reference to a center line of one trench bottomless region 66 among the plurality of trench bottomless regions 66 in the trench extending direction. In an example, the trench bottomless region 66b and the second conductivity type non-forming region 181e are provided such that the center lines match, the second conductivity type forming region 182d and the second conductivity type non-forming region 181d are provided in this order on the positive side of the Y axis with reference to the center line, and the second conductivity type forming region 182e and the second conductivity type non-forming region 181f are provided in this order on the negative side of the Y axis. By arranging in this manner, the length of the path through which the electron current that flows at the time of the switching on of the semiconductor device 100 is flowing can be equalized in each trench bottomless region 66, to reduce the ON loss Eon.

FIG. 2B shows a modified example of the top view of the semiconductor device 100. By using FIG. 2B, differences from FIG. 2A will be described.

In the example shown in FIG. 2B, the trench bottom repetition period P65 is the same as that of the example shown in FIG. 2A. However, the width L65 of the trench bottom region is smaller than that of the example shown in FIG. 2A, and the width L66 of the trench bottomless region is greater than that of the example shown in FIG. 2A. That is, the area occupied by the trench bottomless region 66 in one trench bottom repetition period P65 is greater than that of the example shown in FIG. 2A.

Also, in the example shown in FIG. 2B, the width L181 of the second conductivity type non-forming region 181 and the width L182 of the second conductivity type forming region 182 are smaller than those of the example shown in FIG. 2A. That is, the back-surface-side repetition period P82 is smaller than that of the example shown in FIG. 2A. Thereby, in the trench array direction of the plurality of trench portions, each of the plurality of trench bottomless regions 66 is facing two or more of the plurality of second conductivity type non-forming regions 181.

In the example of FIG. 2B, a total of three second conductivity type non-forming regions 181, that is, one second conductivity type non-forming region 181 having the same center line as that of one trench bottomless region 66, and two second conductivity type non-forming regions 181 provided to be line symmetric on both sides of the second conductivity type non-forming region 181 sandwiching the center line, are provided so as to face one trench bottomless region 66. Even in this case, all of the shortest distances d1 to d6 from the respective end portions 166 of the plurality of trench bottomless regions 66 to the second conductivity type non-forming region 181 are substantially the same. Thereby, the electron current from the trench bottomless region 66 is uniformly distributed, and therefore the ON loss Eon of the semiconductor device 100 can be reduced.

Note that the number of the second conductivity type non-forming regions 181 facing one trench bottomless region 66 is not limited to the present example. One trench bottomless region 66 may face two second conductivity type non-forming regions 181 or may face four or more second conductivity type non-forming regions 181.

FIG. 2C shows a modified example of the top view of the semiconductor device 100. By using FIG. 2C, differences from FIG. 2A will be described.

The second conductivity type non-forming region 181 of the present example has a predetermined length L181x in the trench array direction of the plurality of trench portions (in the present example, the X direction), and has a predetermined width L181y in the trench extending direction of the plurality of trench portions (in the present example, the Y direction). The length L181x and the width L181y may be substantially the same, thereby the second conductivity type non-forming region 181 may be provided to have a substantially square shape in a top view. The length L181x and the width L181y may be different.

In the example of FIG. 2C, the second conductivity type non-forming region 181 and the second conductivity type forming region 182 are alternately and repeatedly arrayed in two directions. The second conductivity type non-forming region 181 and the second conductivity type forming region 182 may have array direction period P82x in the trench array direction of the plurality of trench portions (in the present example, the X direction), and may have an extending direction period P82y in the trench extending direction of the plurality of trench portions (in the present example, the Y direction).

The array direction period P82x and the extending direction period P82y may be substantially the same, thereby the second conductivity type non-forming region 181 and the second conductivity type forming region 182 may be provided to have a dotted pattern in a top view. Even in such a case, the distance from each end portion 166 of each trench bottomless region 66 to the second conductivity type non-forming region 181 can be equalized, to reduce the ON loss Eon. The array direction period P82x and the extending direction period P82y may be different.

FIG. 2D shows a modified example of the top view of the semiconductor device 100. FIG. 2D is an example of a top view in a case in which the depth position at the lower end of the plurality of trench bottom regions 65 is provided closer to the front surface 21 side of the semiconductor substrate 10 than the depth position of the trench bottom portion of the plurality of trench portions, as shown in FIG. 1E.

In FIG. 2D, the plurality of trench bottom regions 65 does not cover the trench bottom portion of the plurality of trench portions. Therefore, in a top view, the plurality of trench bottom regions 65 are provided only in the mesa portion of the transistor portion 70. Also in the example of FIG. 2D, because the electron current flows through the trench bottomless region 66, similar to the case described in FIG. 2A to FIG. 2C, the distance from each end portion 166 of each trench bottomless region 66 to the second conductivity type non-forming region 181 can be equalized, to reduce the ON loss Eon.

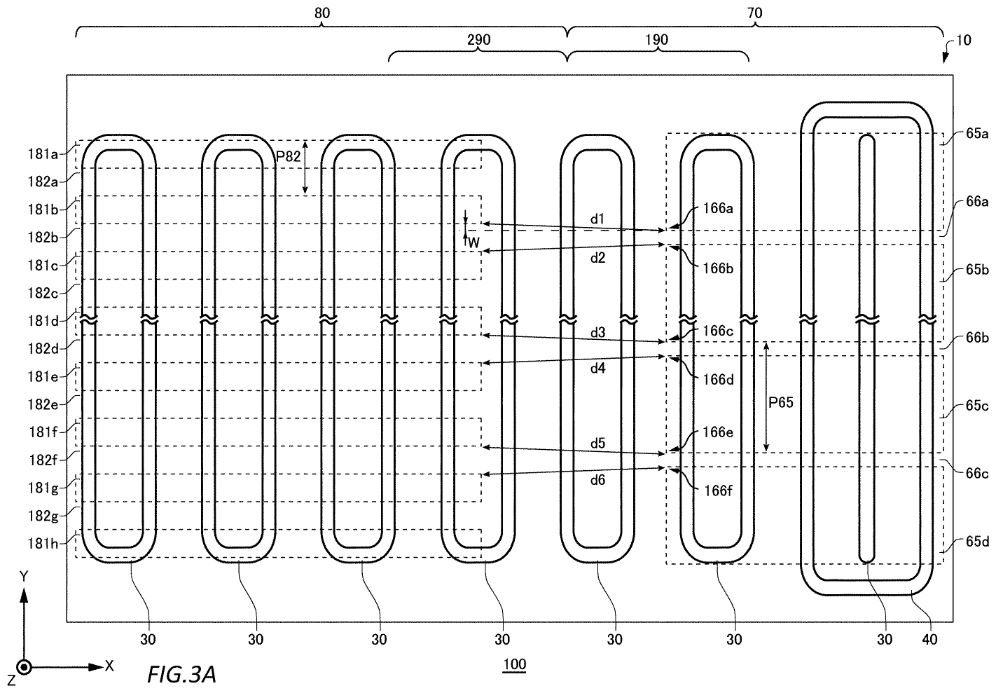

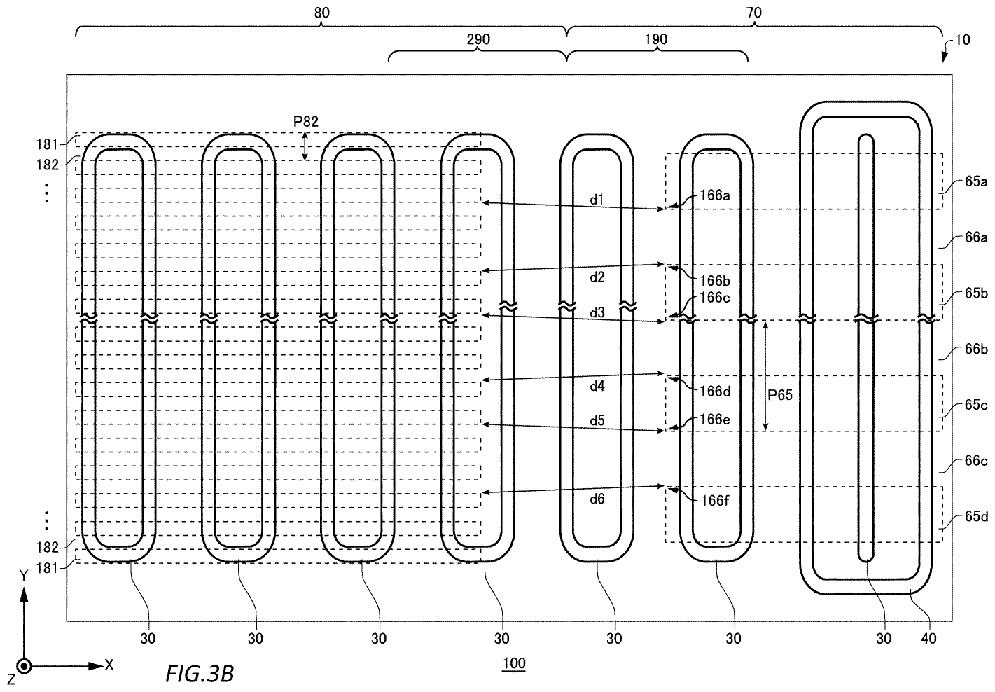

FIG. 3A shows a modified example of the top view of the semiconductor device 100. In the example of FIG. 3A, the trench bottom repetition period P65 and the back-surface-side repetition period P82 are the same as those of the example of FIG. 2A. The example of FIG. 3A is different from the example of FIG. 2A in that the trench bottomless region 66 is facing the second conductivity type forming region 182 in the trench array direction.

In the trench array direction of the plurality of trench portions, each of the plurality of trench bottomless regions 66 may face any of the plurality of second conductivity type forming regions 182. In other words, in the trench array direction, each of the plurality of trench bottomless regions 66 may not face any of the plurality of second conductivity type non-forming regions 181. In the example shown in FIG. 3A, the trench bottomless region 66a is facing the second conductivity type forming region 182b, the trench bottomless region 66b is facing the second conductivity type forming region 182d, and the trench bottomless region 66c is facing the second conductivity type forming region 182f.

Even in a case of arranging in this manner, similar to the example shown in FIG. 2A, all of the shortest distances d1 to d6 from each end portion 166 of the plurality of trench bottomless regions 66 to the second conductivity type non-forming region 181 are substantially the same. Thus, the length of the path through which the electron current that flows at the time of the switching on of the semiconductor device 100 is flowing can be equalized in each trench bottomless region 66, to reduce the ON loss Eon.

The distance W indicates a deviation width between the end portion 166 of the trench bottomless region 66 and the second conductivity type non-forming region 181 in the trench extending direction in a top view. In the present example, because the end portion 166 is not facing the second conductivity type non-forming region 181, the distance W is greater than 0. The distance W may be greater than 0, and may be 50% or less of the width of the trench bottom region 65 in the trench extending direction.

FIG. 3B shows a modified example of the top view of the semiconductor device 100. By using FIG. 3B, differences from FIG. 2B will be described.

In the trench array direction of the plurality of trench portions, each of the plurality of trench bottomless regions 66 may face two or more of the plurality of second conductivity type forming regions 182. In the example of FIG. 3B, a total of three second conductivity type forming regions 182, that is, one second conductivity type forming region 182 having the same center line as that of one trench bottomless region 66, and two second conductivity type forming regions 182 provided to be line symmetric on both sides of the second conductivity type forming region 182 sandwiching the center line, are provided so as to face one trench bottomless region 66. Even in this case, all of the shortest distances d1 to d6 from the respective end portions 166 of the plurality of trench bottomless regions 66 to the second conductivity type non-forming region 181 are substantially the same. Thereby, the electron current from the trench bottomless region 66 is uniformly distributed, and therefore the ON loss Eon of the semiconductor device 100 can be reduced.

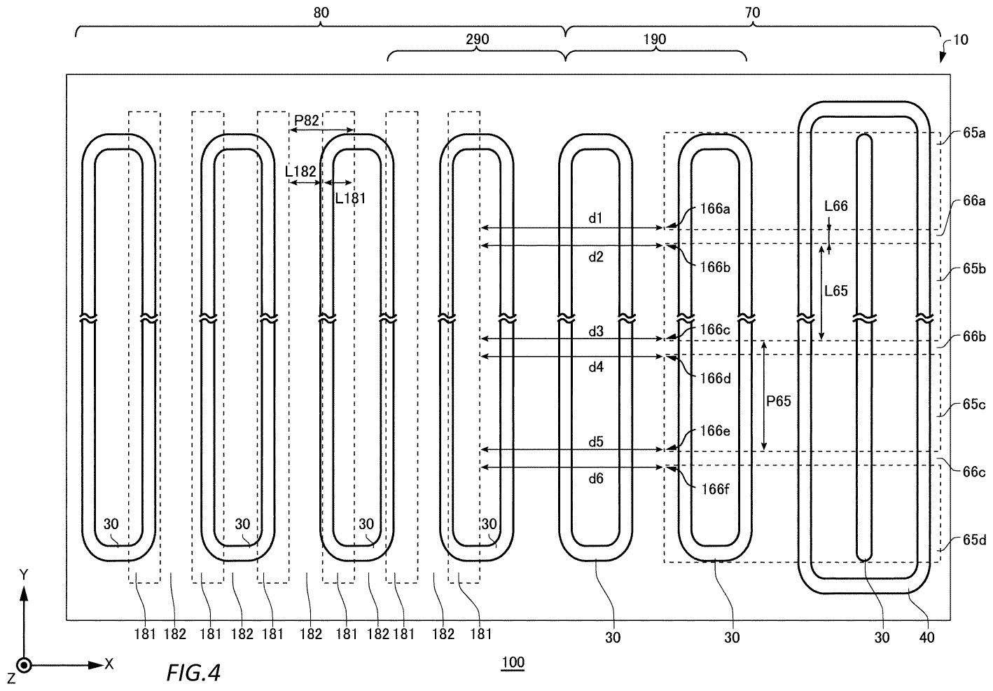

FIG. 4 shows a modified example of the top view of the semiconductor device 100. By using FIG. 4, differences from FIG. 2A will be described.

In the example of FIG. 4, the second conductivity type non-forming region 181 and the second conductivity type forming region 182 extend in the trench extending direction and are alternately arranged in the trench array direction. In the example of FIG. 4, because the second conductivity type non-forming region 181 is provided to be orthogonal to the array direction of the plurality of trench bottomless regions 66, all of the shortest distances d1 to d6 from each end portion 166 of the plurality of trench bottomless regions 66 to the second conductivity type non-forming region 181 are the same. Thereby, the electron current from the trench bottomless region 66 is uniformly distributed, and therefore the ON loss Eon of the semiconductor device 100 can be reduced.

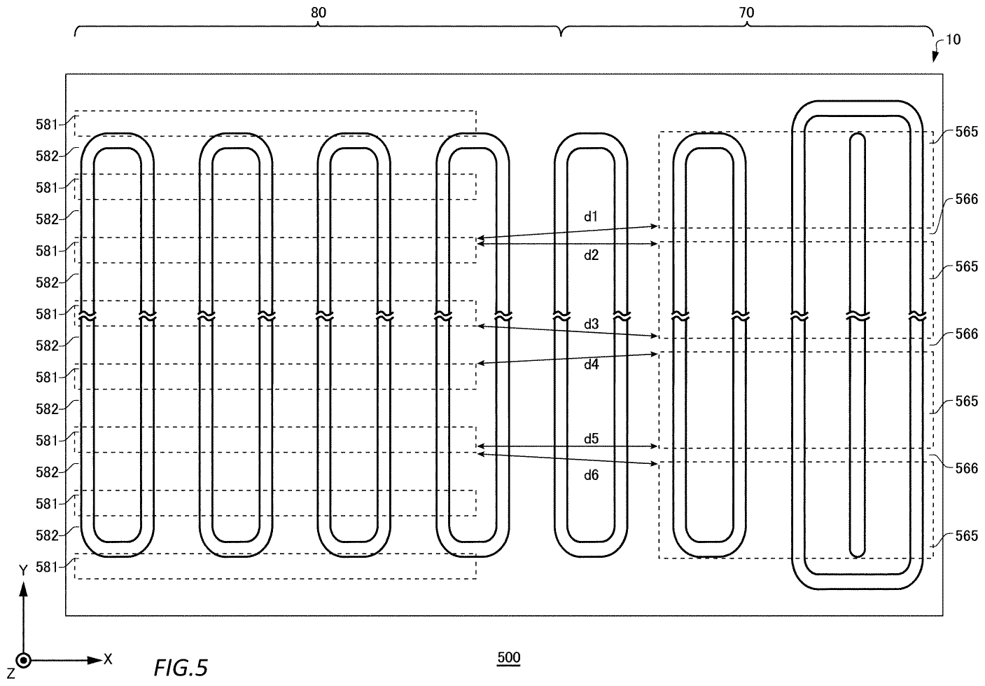

FIG. 5 shows an example of a top view of a semiconductor device 500 of a comparative example. The semiconductor device 500 of the comparative example has a plurality of trench bottom regions 565 provided repeatedly in the trench extending direction of the plurality of trench portions and a plurality of trench bottomless regions 566 provided repeatedly in the trench extending direction and sandwiched between the plurality of trench bottom regions 565. The semiconductor device 500 of the comparative example extends in the trench array direction, and has a second conductivity type non-forming region 581 and a second conductivity type forming region 582 alternately arranged in the trench extending direction.

In the semiconductor device 500 of the comparative example, there is no restriction between the position at which the trench bottomless region 566 is provided and the position at which the second conductivity type non-forming region 581 is provided. That is, in the semiconductor device 500 of the comparative example, the second conductivity type non-forming region 581 and the second conductivity type forming region 582 are not provided to be line symmetric with reference to the center line of one trench bottomless region 566.

In the semiconductor device 500 of the comparative example, because there is no restriction between the position at which the trench bottomless region 566 is provided and the position at which the second conductivity type non-forming region 581 is provided, the shortest distance from the end portion of each trench bottomless region 566 to the second conductivity type non-forming region 581 is different for each trench bottomless region 566. That is, in the semiconductor device 500 of the comparative example, the shortest distances d1 to d6 are not substantially the same.

Because the semiconductor device 100 of the present example has a specific restriction between the position at which the trench bottomless region is provided and the position at which the second conductivity type non-forming region is provided, the shortest distance from each end portion of the plurality of trench bottomless regions to the second conductivity type non-forming region can be equalized. That is, all of the shortest distances d1 to d6 from each end portion of the plurality of trench bottomless regions to the second conductivity type non-forming region can be substantially the same.

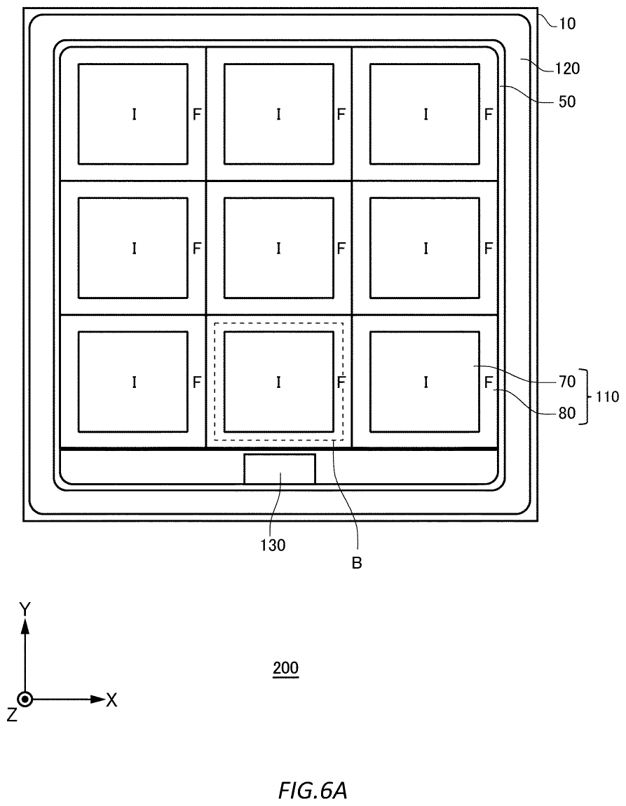

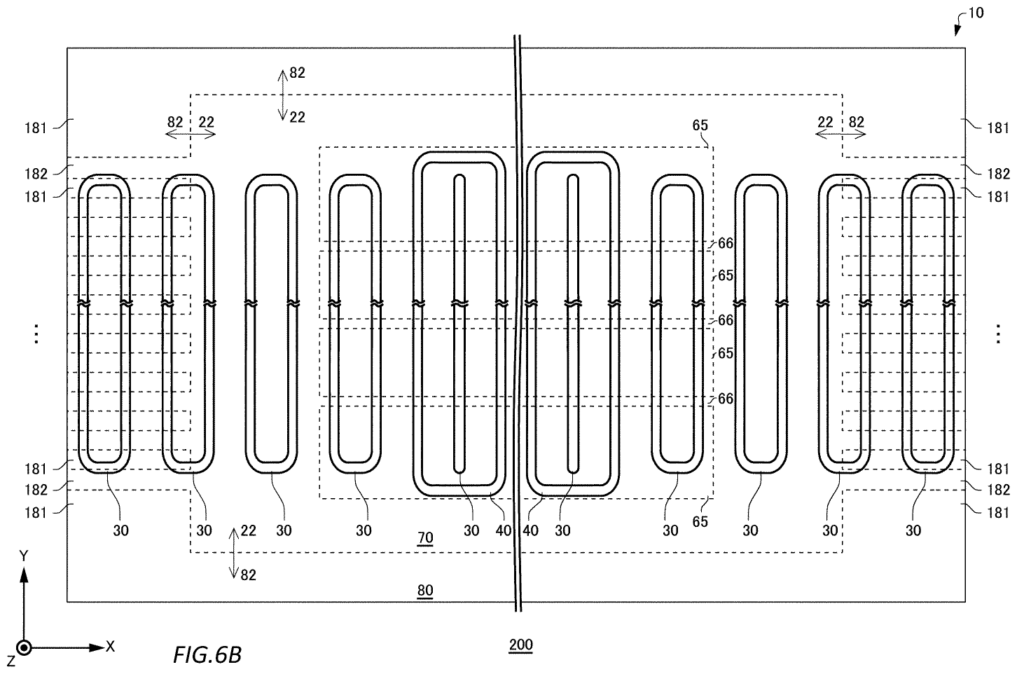

FIG. 6A shows an example of the top view of the semiconductor device 200. The semiconductor device 200 is a semiconductor chip having a transistor portion 70 and a diode portion 80.

The transistor portion 70 and the diode portion 80 of the semiconductor device 200 have a different shape from that of the semiconductor device 100. In the semiconductor device 200, the diode portion 80 is provided to surround the outer circumference of the transistor portion 70. The semiconductor device 200 may comprise a plurality of unit structures with the outer circumference of the transistor portion 70 surrounded by the diode portion 80. The semiconductor device 200 of the present example comprises a total of nine unit structures, with the unit structure repeatedly arranged three times in the X axis direction and the Y axis direction, respectively.

FIG. 6B shows an example of a top view of the semiconductor device 200. In the present example, an enlarged view of a region B in FIG. 6A is shown.

A transistor portion 70 has a plurality of trench portions including a gate trench portion 40 and a dummy trench portion 30. A diode portion 80 has a plurality of trench portions including the dummy trench portion 30. Note that the diode portion 80 may not have a trench portion.

The transistor portion 70 has a plurality of trench bottom regions 65 provided repeatedly in a trench extending direction of the plurality of trench portions (in the present example, the Y axis direction). The transistor portion 70 is provided repeatedly in the trench extending direction, and has a plurality of trench bottomless regions 66 sandwiched between a plurality of trench bottom regions 65. The trench bottom region 65 and the trench bottomless region 66 are provided to extend from the transistor portion 70 toward the diode portion 80 in the trench array direction, and terminate without reaching the diode portion 80.

The diode portion 80 of the present example has, in a region facing the plurality of trench bottomless regions 66, a second conductivity type non-forming region 181 and a second conductivity type forming region 182 alternately provided in the trench extending direction of the plurality of trench portions. Thereby, also in a case in which the outer circumference of the transistor portion 70 is surrounded by the diode portion 80, the electron current flowing at the time of switching on of the semiconductor device 200 can be equalized, and the ON loss Eon can be reduced.

The diode portion 80 may not have the second conductivity type forming region 182 in a region that does not face the plurality of trench bottomless regions 66. In the present example, the second conductivity type forming region 182 is not provided in the diode portion 80 adjacent to the transistor portion 70 in the trench extending direction of the plurality of trench portions. In the present example, the electron current does not flow because the trench bottom portion of the gate trench portion 40 in the trench extending direction is covered with the trench bottom region 65. Thus, in a region that does not face the plurality of trench bottomless regions 66, the ON loss Eon of the semiconductor device 200 is not affected even if there is no structure in which the second conductivity type non-forming region 181 and the second conductivity type forming region 182 are alternately arranged.

While the present invention has been described by way of the embodiments, the technical scope of the present invention is not limited to the above-described embodiments. It is apparent to persons skilled in the art that various alterations or improvements can be made to the above described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### Explanation of References

10: semiconductor substrate;
11: anode region;
12: emitter region;
14: base region;
15: first contact region;
16: accumulation region;
17: well region;
18: drift region;
19: second contact region;
20: buffer region;
21: front surface;
22: collector region;
23: back surface;
24: collector electrode;
25: connecting portion;
27: trench contact portion;
30: dummy trench portion;
31: extending part;
32: dummy dielectric film;
33: connecting part;
34: dummy conductive portion;
38: interlayer dielectric film;
40: gate trench portion;
41: extending part;
42: gate dielectric film;
43: connecting part;
44: gate conductive portion;
50: gate metal layer;
52: emitter electrode;
54: contact hole;
55: contact hole;
56: contact hole;
65: trench bottom region;
66: trench bottomless region;
70: transistor portion;
71: mesa portion;
80: diode portion;
81: mesa portion;
82: back-surface-side region;
82-1: first conductivity type portion;
82-2: second conductivity type portion;
100: semiconductor device;
110: active region;
120: peripheral region;
130: gate pad;
151: first lifetime control region;
152: second lifetime control region;
166: end portion;
181: second conductivity type non-forming region;
182: second conductivity type forming region;
190: first boundary portion;
191: mesa portion;
200: semiconductor device;
290: second boundary portion;
291: mesa portion;
500: semiconductor device;
565: trench bottom region;
566: trench bottomless region;
581: second conductivity type non-forming region;
582: second conductivity type forming region.

What is claimed is:

1. A semiconductor device comprising a transistor portion and a diode portion, the semiconductor device comprises:
a drift region of a first conductivity type provided in a semiconductor substrate;
a plurality of trench portions extending in a predetermined trench extending direction in a front surface side of the semiconductor substrate; and
a collector region of a second conductivity type provided below the drift region, wherein the transistor portion includes:
a base region of the second conductivity type that is provided above the drift region;
an emitter region of the first conductivity type with a doping concentration higher than that of the drift region;
a first contact region of the second conductivity type having a doping concentration higher than that of the base region;
a plurality of trench bottom regions of the second conductivity type that are provided below the base region and provided repeatedly in the trench extending direction; and
a plurality of trench bottomless regions that are provided repeatedly in the trench extending direction and sandwiched between the plurality of trench bottom regions, wherein the diode portion has:
an anode region of the second conductivity type provided above the drift region; and
a back-surface-side region provided below the drift region, and wherein
the back-surface-side region includes a first conductivity type portion of the first conductivity type and a second conductivity type portion of the second conductivity type;
the first conductivity type portion and the second conductivity type portion are provided such that a repetitive structure is formed, in which a second conductivity type forming region in which the second conductivity type portion is formed and a second conductivity type non-forming region in which the second conductivity type portion is not formed are alternately and repeatedly arrayed in a predetermined direction in a top view; and
in a top view, a shortest distance from each end portion of the plurality of trench bottomless regions to the second conductivity type non-forming region is 85% or more and 115% or less of a predetermined reference value.

2. The semiconductor device according to claim 1, wherein the second conductivity type non-forming region and the second conductivity type forming region extend in the trench extending direction and are alternately arranged in a trench array direction of the plurality of trench portions in a top view.

3. The semiconductor device according to claim 1, wherein the second conductivity type non-forming region and the second conductivity type forming region extend in a trench array direction of the plurality of trench portions and are alternately arranged in the trench extending direction in a top view.

4. The semiconductor device according to claim 1, an area of the second conductivity type non-forming region is 30% or more and 70% or less of an area of the back-surface-side region in a top view.

5. The semiconductor device according to claim 1, wherein
the back-surface-side region has a plurality of second conductivity type non-forming regions, each of which is equivalent to the second conductivity type non-forming region, and
in a trench array direction of the plurality of trench portions, each of the plurality of trench bottomless regions is facing any of the plurality of second conductivity type non-forming regions.

6. The semiconductor device according to claim 1, wherein
the back-surface-side region has a plurality of second conductivity type non-forming regions, each of which is equivalent to the second conductivity type non-forming region, and
in a trench array direction of the plurality of trench portions, each of the plurality of trench bottomless regions is facing two or more of the plurality of second conductivity type non-forming regions.

7. The semiconductor device according to claim 1, wherein
the back-surface-side region has a plurality of second conductivity type forming regions, each of which is equivalent to the second conductivity type forming region, and
in a trench array direction of the plurality of trench portions, each of the plurality of trench bottomless regions is facing any of the plurality of second conductivity type forming regions.

8. The semiconductor device according to claim 1, wherein
the back-surface-side region has a plurality of second conductivity type forming regions, each of which is equivalent to the second conductivity type forming region, and
in a trench array direction of the plurality of trench portions, each of the plurality of trench bottomless regions is facing two or more of the plurality of second conductivity type forming regions.

9. The semiconductor device according to claim 1, wherein an area of the plurality of trench bottomless regions sandwiched by the plurality of trench bottom regions is 85% or more and 115% or less of each predetermined reference value.

10. The semiconductor device according to claim 1, wherein
the transistor portion is provided to be adjacent to the diode portion, and has a first boundary portion that is not provided with the first contact region above the drift region, and
the diode portion has:
a second contact region of a second conductivity type that is provided above the drift region and that has a higher doping concentration than that of the anode region, and
a second boundary portion that is provided to be adjacent to the transistor portion and that is not provided with the second contact region, and
in the second boundary portion, a back surface of the semiconductor substrate has the first conductivity type portion.

11. The semiconductor device according to claim 1, wherein the second conductivity type non-forming region and the second conductivity type forming region are provided to b line symmetric with reference to a center line of one trench bottomless region of the plurality of trench bottomless regions in the trench extending direction.

12. The semiconductor device according to claim 1, wherein
the second conductivity type non-forming region and the second conductivity type forming region are alternately arranged in a predetermined back-surface-side repetition period,
the plurality of trench bottom regions are repeatedly arranged in a predetermined trench bottom repetition period, and
the trench bottom repetition period is greater than the back-surface-side repetition period.

13. The semiconductor device according to claim 12, wherein the back-surface-side repetition period is 10 μm or more and 100 μm or less.

14. The semiconductor device according to claim 12, wherein the trench bottom repetition period is an integer multiple of the back-surface-side repetition period.

15. The semiconductor device according to claim 1, wherein
the first conductivity type portion is provided to be in contact with a back surface of the semiconductor substrate, and
the second conductivity type portion is provided to be in contact with the back surface of the semiconductor substrate and adjacent to the first conductivity type portion.

16. The semiconductor device according to claim 1, wherein
the first conductivity type portion is provided to be in contact with a back surface of the semiconductor substrate, and
the second conductivity type portion is provided above the first conductivity type portion.

17. The semiconductor device according to claim 1, wherein in a depth direction of the semiconductor substrate, a depth position at a lower end of the plurality of trench bottom regions is provided closer to a side of the front surface than a depth position of a trench bottom portion of the plurality of trench portions.

18. The semiconductor device according to claim 1, wherein the diode portion is provided to surround an outer circumference of the transistor portion.

19. The semiconductor device according to claim 1, wherein the second conductivity type forming region is not provided in the diode portion adjacent to the transistor portion in the trench extending direction.

20. The semiconductor device according to claim 1, wherein the second conductivity type non-forming region and the second conductivity type forming region are arranged alternately in a trench array direction of the plurality of trench portions and the trench extending direction in a top view, respectively.
